(19) United States
(12) Patent Application Publication
(10) Pub. No.: US 2026/0211057 A1
(43) Pub. Date: Jul. 23, 2026

(54) METHOD FOR ESTIMATING THE SELF-DISCHARGE OF AN ELECTROCHEMICAL ELEMENT OF A BATTERY, AND ASSOCIATED METHODS AND DEVICES

(71) Applicant: SAFT, LEVALLOIS PERRET (FR)

(72) Inventors: Pierre-Olivier LAMARE, BORDEAUX (FR); Sébastien BENJAMIN, LEOGNAN (FR); Philippe LAFLAQUIERE, SAINT CAPRAIS DE BORDEAUX (FR); Gérard BARRAILH, MONEIN (FR)

(73) Assignee: SAFT, LEVALLOIS PERRET (FR)

(21) Appl. No.: 19/139,784

(22) PCT Filed: Dec. 19, 2023
(86) PCT No.: PCT/EP2023/086538

§ 371 Date: Jun. 16, 2025

(30) Foreign Application Priority Data
Dec. 20, 2022 (FR) FR2213987

(51) Int. Cl. G01R 31/396; G01R 31/367; G01R 31/3842

(52) U.S. Cl. CPC G01R 31/396; G01R 31/367; G01R 31/3842

(57) ABSTRACT

A method for estimating the self-discharge of an electrochemical element on which a balancing current is applied, comprises: obtaining the capacity of the electrochemical element, obtaining a first measurement values comprising measurements of the current and the balancing current applied at first instants, obtaining second measurement values comprising measurements of the state of charge at second instants, and estimating the value of the self-discharge at a second estimation instant by applying an estimation function to the obtained values. The estimation function calculates a first contribution corresponding to a variation of the state of charge and a second contribution corresponding to an accumulation of charge related to the first values.

### CROSS REFERENCE TO RELATED APPLICATIONS

The present application is a U.S. National Phase Application under 35 U.S.C. § 371 of International Patent Application No. PCT/EP2023/086538 filed Dec. 19, 2023, which claims priority of French Patent Application No. 2213987 filed Dec. 20, 2022. The entire contents of which are hereby incorporated by reference.

### FIELD

This invention relates to a method for estimating the self-discharge of at least one electrochemical element of a battery. It also relates to methods implementing the aforementioned estimation method, namely a method for evaluating the dispersion of the state of charge and a method for controlling the current balancing of the electrochemical elements of a battery. The invention also relates to a calculator, a management system, and an associated battery.

### BACKGROUND

Typically, a battery comprises one or more current accumulators, also called electrochemical generators, cells, or elements. An accumulator is a device for producing electricity wherein chemical energy is converted into electrical energy. The chemical energy comes from electrochemically active compounds deposited on at least one face of electrodes arranged in the accumulator. The electrical energy is produced by electrochemical reactions during a discharge of the accumulator. The electrodes, arranged in a container, are electrically connected to current output terminals that ensure electrical continuity between the electrodes and an electrical consumer to which the accumulator is associated.

To increase the electrical power delivered, several sealed accumulators can be associated with each other to form a battery. Thus, a battery can be divided into modules, each module comprising one or a plurality of accumulators connected in series and/or in parallel. Thus, a battery can, e.g., include one or a plurality of parallel branches of accumulators connected in series and/or one or a plurality of parallel branches of modules connected in series.

A charging circuit is generally provided to which the battery can be connected to recharge the accumulators.

Furthermore, an electronic management system comprising measurement sensors and a control electronic circuit, more or less advanced depending on the applications, can be associated with the battery. Such a system allows for organizing and controlling the charge and discharge of the battery, to balance the charge and discharge of the different accumulators of the battery with respect to each other.

To balance the charge and discharge of the different accumulators, it is necessary to be able to carefully obtain the current imbalance between these accumulators. For this purpose, it is known to perform a complete discharge to determine the state of charge and then to compensate for the observed differences in the state of charge by balancing the accumulators, but this involves frequently shutting down the entire system, which can be problematic for certain applications.

### SUMMARY

An aim of the invention is to provide a method that allows for effectively determining the quantities involved in the current balancing of electrochemical elements of a battery and for better controlling this balancing.

In particular, a good knowledge of self-discharge dispersions would allow for more intelligent control of the balancing, allowing these effects to be compensated for without having to perform a complete discharge.

To this end, the description describes a method for estimating the self-discharge of at least one electrochemical element of a battery relative to a reference value, a balancing current specific to the electrochemical element being applied to each electrochemical element, the method being implemented by a calculator, the method comprising, for at least one electrochemical element, the steps of:
obtaining:
the capacity of the electrochemical element,
first measurement values, the first values comprising measurements or estimates of the current of the electrochemical element and the balancing current applied to the electrochemical element at the first instants, and
second measurement values, the second values comprising measurements or estimates of the state of charge of the electrochemical element at the second instants,
estimation of the value of the self-discharge of the electrochemical element at a second instant, denoted second estimation instant, by applying an estimation function to the capacity, the first measurement values, and the second measurement values, the estimation function calculating two contributions to the self-discharge, a first contribution corresponding to the variation of the state of charge of the electrochemical element between the second estimation instant and a previous second instant and a second contribution corresponding to the accumulation of charge in the electrochemical element related to the first measurement values in the time interval between the previous second instant and the second estimation instant.

According to particular embodiments, the method for estimating the self-discharge presents one or more of the following characteristics, taken individually or according to all technically possible combinations:
the reference value is the self-discharge value of another electrochemical element, the other electrochemical element being, preferably, the electrochemical element for which the self-discharge value at the previous second instant is the highest, the estimation function also taking into account a third contribution corresponding to the variation of the state of charge of the other electrochemical element between the second estimation instant and the previous second instant and a fourth contribution corresponding to the accumulation of charge in the other electrochemical element related to the first measurement values in the time interval between the previous second instant and the second estimation instant.
the estimation function is a weighted sum of the contributions and the self-discharge value relative to the reference value at the previous second instant.
the contributions are weighted by a same gain coefficient, the gain coefficient depending:
on a first parameter, the first parameter being the product of the capacity of the electrochemical element with the time interval between the previous second instant and the second estimation instant,
on a second parameter, the second parameter being an adjustable value, and possibly
on a third parameter taking into account the uncertainty of the second measurements, the third parameter depending, preferably, on the ratio between the uncertainty of the second measurements and the value of the contributions,
the gain coefficient preferably being a hyperbolic function that can be written in the form:

$$P 3 \frac{P 1}{P {1}^{2} + P {2}^{2}}$$

with P1 the first parameter, P2 the second parameter, and P3 the third parameter.

The description also relates to a method for evaluating the dispersion of the state of charge of a plurality of electrochemical elements of a battery, the plurality of electrochemical elements including, preferably, all the electrochemical elements of the battery, the method for evaluating the dispersion of the state of charge being implemented by a calculator and comprising the steps of:
implementation, for the plurality of electrochemical elements of the battery (10), of the steps of a method for estimating the self-discharge of an electrochemical element of a battery relative to a reference value, the method being as described hereinabove, to obtain a self-discharge value relative to the reference value for each electrochemical element of the plurality of electrochemical elements, and
determination of the dispersion of the state of charge within the plurality of electrochemical elements at an evaluation instant as the difference between the state of charge of the electrochemical element of the plurality of electrochemical elements that is the highest and the state of charge of the electrochemical element of the plurality of electrochemical elements that is the lowest, the determination step comprising the application of an evaluating function to values used or obtained during the implementation step.

According to particular embodiments, the method for evaluating the dispersion of the state of charge presents one or more of the following characteristics, taken individually or according to all technically possible combinations:
the battery is provided with a balancing circuit allowing a respective balancing current to be applied in each electrochemical element of the plurality of electrochemical elements, the balancing circuit presenting two states, an active state and an inactive state,
the evaluating function applied being selected between several sub-functions according to at least one predefined criterion, the at least one predefined criterion preferably being that the evaluation instant corresponds to the second estimation instant and the state of the balancing circuit at the evaluation instant.
the sub-functions are selected from:
a calculating sub-function calculating the maximum of the difference in states of charge at the evaluation instant.
an estimation function applied to the values obtained at the end of the implementation step, the estimation function calculating two contributions to the dispersion, a first contribution related to the self-discharge specific to each electrochemical element and a second contribution related to the maximum self-discharge of all the electrochemical elements of the plurality of electrochemical elements, and
a sub-function is an estimation function applied to the values obtained at the end of the implementation step, the estimation function calculating three contributions to the dispersion, a first contribution related to the self-discharge specific to each electrochemical element, a second contribution related to the maximum self-discharge of all the electrochemical elements of the plurality of electrochemical elements, and a third contribution related to the balancing currents applied to the electrochemical elements of the plurality of electrochemical elements.
when a criterion according to which the evaluation instant corresponds to the second estimation instant is verified, the evaluating function selected is the calculating sub-function, and when the balancing circuit is in the active state, the evaluating function selected being the estimation sub-function calculating three contributions, the evaluating function selected is the estimation sub-function calculating two contributions otherwise.

The description also relates to a method for controlling the current balancing of the electrochemical elements of a battery, the battery being provided with a balancing circuit allowing a respective balancing current to be applied in each electrochemical element of the plurality of electrochemical elements, the balancing circuit presenting two states, an active state and an inactive state, the method of control being implemented by a calculator, the method of control including the steps of:
implementation of the steps of the method for evaluating the dispersion of the state of charge of a plurality of electrochemical elements of a battery, the method of evaluation being as previously described, to obtain an evaluated dispersion,
comparison of the evaluated dispersion with a dispersion threshold, and
control of the state of the balancing circuit based on the result of the comparison by setting the balancing circuit to the active state if the evaluated dispersion is greater than or equal to the dispersion threshold possibly decreased by a hysteresis threshold and setting the balancing circuit to the inactive state otherwise.

The description also relates to a method for controlling the current balancing of the electrochemical elements of a battery, the method of control being implemented by a calculator, the method of control including the steps of:
implementation of the steps of the method for evaluating the dispersion of the state of charge of a plurality of electrochemical elements of a battery, the method of evaluation being as previously described, to obtain an evaluated dispersion,
comparison of the evaluated dispersion with a dispersion threshold, and
control of the time interval between two consecutive second instants to be used for subsequent measurements based on the result of the comparison.

According to particular embodiments, the method for controlling the current balancing of the electrochemical elements presents one or a plurality of the following characteristics, taken individually or according to all technically possible combinations:
the control step includes an increment of the time interval by a first time increment when the evaluated dispersion is less than or equal to the threshold and a decrease of the time interval by a second time increment when the evaluated dispersion is less than or equal to the threshold, the time interval being set to a predefined value if the decrease of the second increment leads to a value lower than the predefined value, the first time increment and the second time increment preferably being equal.
the method further includes a step of testing the validity of the measurement, the test step including a test of the amplitude of variation of the dispersion relative to a maximum possible variation value.

The description also relates to a calculator specific to implementing a method as described hereinabove.

The description also concerns a management system for a plurality of electrochemical elements of a battery, the electrochemical elements having terminals, the management system comprising:
a balancing circuit specific to applying a respective balancing current to each of the electrochemical elements of the plurality of electrochemical elements,
for each electrochemical element of the plurality of electrochemical elements:
a current sensor delivered by the electrochemical element,
a balancing current sensor applied, and
a voltage sensor specific to measuring the voltage at the terminals of the electrochemical element, and
a calculator as described hereinabove.

The description also relates to a battery comprising:
electrochemical elements, and
a management system as described hereinabove.

In this description, the expression “specific to” means interchangeably “adapted for”, “adapted to” or “configured for”.

### BRIEF DESCRIPTION OF THE DRAWINGS

Further features and advantages of the invention will become more apparent from the description, which is illustrated by way of non-limiting example in the drawings, which: FIG. 1 is a schematic representation of an example of a battery including an electrochemical element,

FIG. 2 is a graph illustrating an example of a state of charge-open circuit voltage characteristic of the electrochemical element of FIG. 1,

FIG. 3 is a block diagram representation of an example of implementation of a method for estimating the self-discharge of an electrochemical element,

FIG. 4 is a flowchart of an example of implementation of a method for evaluating the dispersion of state of charge within a plurality of electrochemical elements,

FIG. 5 is a flowchart of an example of implementation of a method for controlling the balancing,

FIG. 6 is a flowchart of an example of implementation of another method for controlling the balancing,

FIG. 7 is a flowchart of an example of implementation of yet another method for controlling the balancing,

FIG. 8 is a block representation of the arrangement of the methods of FIGS. 3 to 7, and

FIGS. 9 to 12 presenting experimental results obtained by the Applicant by implementing the methods of FIGS. 3 to 7.

### DETAILED DESCRIPTION

A battery 10 is represented in FIG. 1.

In a manner known per se, a battery is generally an arrangement of a plurality of electrochemical elements but for the sake of simplification of the discussion, a case with a single electrochemical element is described hereinbelow, knowing that the transposition to other arrangements is immediate.

The battery 10 includes an electrochemical element 12 and a management system 14 of the electrochemical element 12.

As explained previously, an electrochemical element 12 is a device for producing electricity wherein chemical energy is converted into electrical energy.

The electrochemical element 12 thereby delivers a current and a voltage between two terminals.

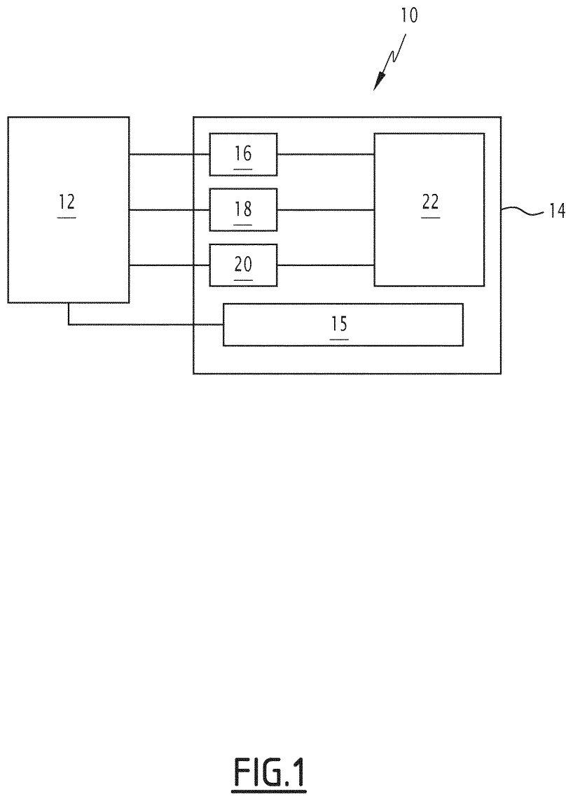

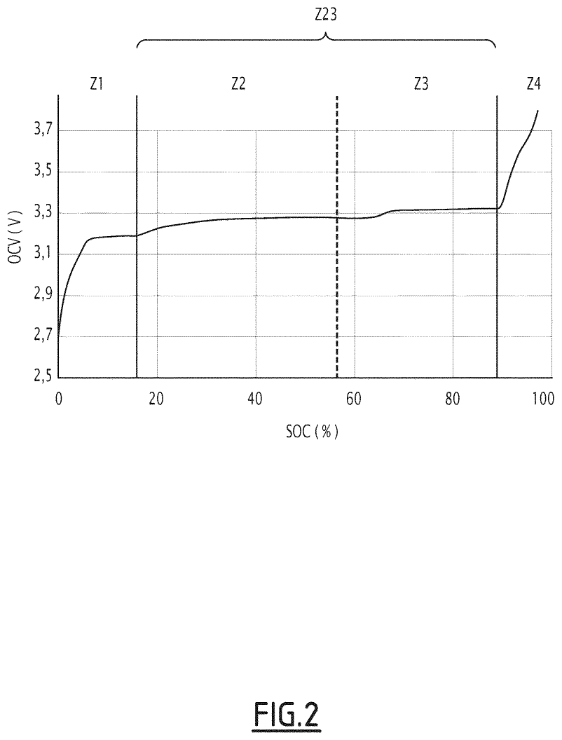

The electrochemical element 12 can present a state of charge SOC-open circuit voltage OCV characteristic as visible in FIG. 2. This characteristic is noted SOC/OCV characteristic in the following.

The state of charge is useful information for the management system 14 to optimize the use and service life of the battery 10. The state of charge is often referred to by the abbreviation SOC which refers to the term “State of Charge”.

The open circuit voltage is often referred to by the abbreviation OCV which refers to the term “Open Circuit Voltage”.

In FIG. 2, the state of charge SOC is expressed as a percentage of a maximum state of charge.

The SOC/OCV characteristic can present, e.g., four zones, a first zone Z1, a second zone Z2, a third zone Z3, and a fourth zone Z4.

The first zone Z1 corresponds to the beginning of the charge and the fourth zone Z4 to the end of the charge.

For the two intermediate zones, as the second zone Z2 and third zone Z3 correspond to a flat portion, the term flat portion (Z23) will be used in the following.

The flat portion Z23 is a portion wherein the variation of open circuit voltage OCV is less than 30 mV for a variation of at least 10% of the state of charge SOC.

Such a type of SOC/OCV characteristic is found notably when the electrochemical element 12 is an electrochemical element comprising a cathodic active material selected from the following groups or their mixtures:
i) a compound of formula LiₓFe_{1-y}M_{y}PO₄ where M is selected from the group consisting of B, Mg, Al, Si, Ca, Ti, V, Cr, Mn, Co, Ni, Cu, Zn, Y, Zr, Nb, and Mo; and 0.8≤x≤1.2; 0≤y≤0.6,
ii) a compound of formula LiₓMn_{1-y-z}M′_{y}M″_{z}PO₄, where M′ and M″ are different from each other and are selected from the group consisting of B, Mg, Al, Si, Ca, Ti, V, Cr, Fe, Co, Ni, Cu, Zn, Y, Zr, Nb, and Mo, with 0.8≤x≤1.2; 0≤y≤0.6; 0.0≤z≤0.2,
iii) a compound of formula LiₓMn_{2-y-z}Ni_{y}M_{z}O_{4-d-c}F_{c} where M represents one or more elements selected from the group consisting of B, Mg, Al, Si, Ca, Ti, V, Cr, Fe, Co, Cu, Zn, Y, Zr, Nb, Ru, W, and Mo; and 1≤x≤1.4; 0<y≤0.6; 0≤z≤0.2; 0≤d≤1; 0≤c≤1,
iv) a compound of formula LiₓMn_{2-y-z}M′_{y}M″₂O₄, where M′ and M″ are selected from the group consisting of B, Mg, Al, Si, Ca, Ti, V, Cr, Fe, Co, Ni, Cu, Zn, Y, Zr, Nb, and Mo; M′ and M″ being different from each other, and 1≤x≤1.4; 0≤y≤0.6; 0≤z≤0.2, and
v) a compound of formula LiVPO₄F.

The anodic active material is not particularly limited. It is a material capable of inserting lithium into its structure. It can be selected from lithium compounds, carbon materials such as graphite, coke, carbon black, and vitreous carbon. It can also be based on tin, silicon, carbon and silicon-based compounds, carbon and tin-based compounds, or carbon, tin, and silicon-based compounds. It can also be a lithium titanate oxide such as Li₄Ti₅O₁₂ or a niobium titanium oxide such as TiNb₂O₇.

Of course, these examples are non-limiting and the methods described later can be used for any type of electrochemical element 12.

The management system 14 is a system specific to managing the electrochemical element 12.

The management system 14 includes a balancing circuit 15 and, for each electrochemical element 12, a voltage sensor 16, a first current sensor 18, and a second current sensor 20.

The balancing circuit 15 is specific to applying a respective balancing current to each of the electrochemical elements 12 of the battery.

The balancing circuit 15 presents two states, namely an active state wherein the balancing circuit 15 applies a balancing current and an inactive state wherein the balancing circuit 15 does not apply the balancing current.

The voltage sensor 16 is specific to measuring the voltage at the terminals of the electrochemical element 12.

The first current sensor 18 is specific to measuring the current delivered by the electrochemical element 12.

The second current sensor 20 is specific to measuring the balancing current applied to the electrochemical element 12 by the balancing circuit 15.

The calculator 22 is specific to implementing a plurality of methods that will be described hereinbelow.

The calculator 22 is an electronic circuit designed to manipulate and/or transform data represented by electronic or physical quantities in the calculator's registers and/or memories into other similar data corresponding to physical data in the register memories or other types of display devices, transmission devices, or storage devices.

As specific examples, the calculator 22 comprises a single-core or multi-core processor (such as a central processing unit (CPU), a graphics processing unit (GPU), a microcontroller, and a digital signal processor (DSP)), a programmable logic circuit, such as an application-specific integrated circuit (ASIC), a field-programmable gate array (FPGA), a programmable logic device (PLD), and programmable logic arrays (PLA), a state machine, a logic gate, and discrete hardware components.

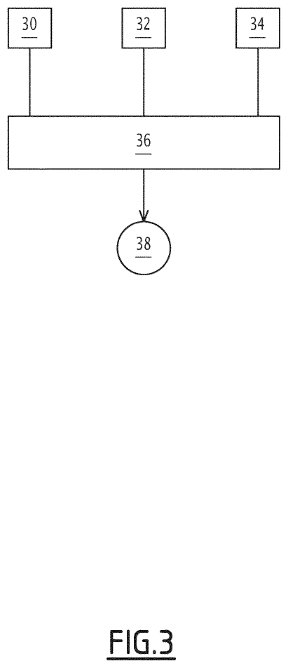

A functioning of the calculator 22 is now described with reference to FIG. 3, which is a flowchart illustrating an example of implementation of a method for estimating the self-discharge of at least one electrochemical element 12 of the battery 10 relative to a reference value.

According to the example described, the estimation method includes an obtaining step and an estimation step.

During an obtaining step, the calculator 22 obtains the capacity of the electrochemical element 12, the first measurement values, and the second measurement values.

This obtaining step is schematized in FIG. 3 by squares 30, 32, and 34 corresponding respectively to the capacity, the first values, and the second values.

The capacity may be obtained by any means, notably by implementing an estimation. For the following, the capacity is noted Qⁱ with i an index used to identify the electrochemical elements 12. The capacity Qⁱ is thereby the capacity of the i-th electrochemical element 12 of the battery 10.

Indeed, the electrochemical elements 12 are assumed here to be connected in series.

The first measurement values are values of the current of the electrochemical element 12 and the balancing current applied to the electrochemical element 12.

In the following,

$${I}_{bat}^{i} and {I}_{bal}^{i}$$

designate respectively the current of the electrochemical element 12 with index i and the balancing current applied to the electrochemical element 12 with index i.

Each of the first measurement values is obtained at first instants.

According to the example described, the first measurement values are obtained at regular intervals, this time interval being noted Δt.

According to the example described, the two current sensors 18 and 20 measure these current values.

Alternatively, the first measurement values are obtained by an estimation.

The first measurement values are thereby obtained either by measurements or by estimations or if it is relevant, e.g., because certain measurements are not feasible, at certain first instants by measurements and estimations.

The second measurement values are values of the state of charge of the electrochemical element.

Each of the second measurement values is obtained at second instants.

The second instants are noted tₙ in the following, the index n being an integer.

The second measurement values can thereby be noted

$${SOC}_{n}^{i} ,$$

i designating the i-th electrochemical element 12 and n the second instant tₙ.

As with the first measurement values, the second measurement values are obtained either by measurements or estimations.

For a measurement, it is necessary to perform a complete discharge or charge.

Such an operation is often referred to as a “snapshot”.

At the end of the obtaining step, the calculator 22 thereby has a plurality of values for several physical quantities and will use these values to estimate the self-discharge of the electrochemical element 12.

During the estimation step, the calculator 22 thereby estimates the value of the self-discharge of the electrochemical element 12 at a second instant, denoted second estimation instant, by applying an estimation function to the capacity, the first measurement values, and a second measurement value.

This estimation step is symbolized by a rectangle 36.

According to a first example of embodiment of the obtaining step, the reference value is zero and the estimation function is an observer based on a formula that can be qualified as “coulometry”.

More precisely, the state of charge can be expressed by the following formula:

$$SOC ( k + 1 ) = SOC ( k ) + \frac{1}{Q} I ( k )$$

The estimation function thereby seeks to obtain the estimation of the self-discharge of the considered electrochemical element.

Generally, the self-discharge current is expressed in capacity loss per month of the considered electrochemical element 12.

In other words, a 3% capacity loss per month of an electrochemical element of 180 Ah corresponds to a current of

$$\frac{0.03 * 180}{24 * 30} = 7.5 mA .$$

It can also be specified here that the convention used for the current is the receiver convention, so that the discharge current is negative and thereby the self-discharge currents to be estimated are negative currents.

In this case, the estimation function calculates two contributions to the self-discharge, a first contribution and a second contribution.

The first contribution corresponds to the variation of the state of charge of the electrochemical element 12 between the second estimation instant and a previous second instant.

The second contribution corresponds to the accumulation of charge in the electrochemical element 12 related to the first measurement values in the time interval between the previous second instant and the second estimation instant.

More precisely, the estimation function is a weighted sum of the contributions and the self-discharge value relative to the reference value at the previous second instant.

The contributions are here weighted by the same gain coefficient.

The estimation function is written mathematically:

$${\hat{I}}_{s d , n + 1}^{i} - {\hat{I}}_{s d , n}^{i} = {K}_{n}^{i} ( {SOC}^{i} ( {t}_{n + 1} ) - {SOC}^{i} ( {t}_{n} ) - {θ}^{i} Δ t ( M {\hat{I}}_{s d , n}^{i} + {\sum }_{k = 0}^{M - 1} ( {I}_{b a l}^{i} + {I}_{b a t} ) ( {t}_{n} + k Δ t ) ) ) ( {SOC}^{i} ( {t}_{n + 1} ) - {SOC}^{i} ( {\overline{t}}_{n} ) - {θ}^{i} Δ t ( M {\hat{I}}_{s d , n}^{i} + {\sum }_{k = 0}^{M - 1} ( {I}_{b a l}^{i} + {I}_{b a t} ) ( {t}_{n} + k Δ t ) ) )$$

Where:

$$M = \frac{{t}_{n + 1} - {t}_{n}}{Δ t} ,$$

$${θ}^{i} = \frac{1}{{Q}^{i}} ,$$

$$( {I}_{b a l}^{i} + {I}_{b a t} ) ( {t}_{n} + k Δ t )$$

corresponds to the value of

$${I}_{b a l}^{i} + {I}_{b a t}$$

at times tₙ+kΔt, k being an integer varying between 0 and M−1, and

$${K}_{n}^{i}$$

is the gain coefficient.

According to a first embodiment, the gain coefficient

$${K}_{n}^{i}$$

depends on two parameters, a first parameter being the product of the capacity of the electrochemical element with the time interval between the previous second instant and the second estimation instant and the second parameter being an adjustable value.

Moreover, the gain coefficient is a hyperbolic function that can be written in the form:

$$\frac{P 1}{P {1}^{2} + P {2}^{2}}$$

with P1 the first parameter and P2 the second parameter.

As a particular example, the gain coefficient

$${K}_{n}^{i}$$

is given by:

$${K}_{n}^{i} = \frac{{θ}^{i} Δ t M}{{γ}^{2} + {( {θ}^{i} Δ t M )}^{2}}$$

Where:
γ is an adjustment parameter (second parameter P2) that allows the update speed of the observer to be controlled.

According to a second embodiment, the gain coefficient

$${K}_{n}^{i}$$

used also takes into account a third parameter, the third parameter taking into account the uncertainty of the second measurements.

For example, the gain coefficient

$${K}_{n}^{i}$$

is a hyperbolic function that can be written in the form:

$$P 3 \frac{P 1}{P {1}^{2} + P {2}^{2}}$$

with P1 the first parameter, P2 the second parameter, and P3 the third parameter.

The gain coefficient

$${K}_{n}^{i}$$

then becomes:

$${K}_{n}^{i} = \frac{{α}_{n}^{i} {θ}^{i} Δ t M}{{γ}^{2} + {( {θ}^{i} Δ t M )}^{2}}$$

Where

$${α}_{n}^{i}$$

designates the third parameter and depends on the ratio between the uncertainty of the second measurements and the value of the contributions.

According to a particular example, the third parameter

$${α}_{n}^{i}$$

verifies the following relation:

$${α}_{n}^{i} = {ρ}_{n}^{i} max ( 1 - \frac{{η}_{1} + {η}_{2} + {θ}^{i} Δt {\sum }_{j = 1}^{M} {κ}_{j}}{\vert {e}_{n}^{i} \vert + δ} , 0 )$$

Where:

$${ρ}_{n}^{i}$$

is an adjustment parameter, this parameter verifying

$$0 \leq {ρ}_{n}^{i} \leq 1$$

η₁ and

$${K}_{n}^{i}$$

represent the uncertainty on the state of charge measurement at the second instants tₙ₊₁ and tₙ respectively,

$${θ}^{i} Δ t {\sum }_{j = 1}^{M} {κ}_{j}$$

corresponds to the uncertainties in the measurements of the currents of the electrochemical elements 12 and the self-discharge,
δ designates a relatively small positive number, the role of which is to avoid division by 0 if the term

$${e}_{n}^{i}$$

is zero, and

$${e}_{n}^{i}$$

designates the error on the self-discharge estimation, this value being given according to the following formula:

$${e}_{n}^{i} = {SOC}_{n + 1}^{i} - {SOC}_{n}^{i} - {θ}^{i} Δ t ( M {\hat{I}}_{sd , n}^{i} + {\sum }_{k = 0}^{M - 1} ( {I}_{bal}^{i} ( {t}_{n} + k Δ t ) + {I}_{bal} ( {t}_{n} + k Δ t ) ) ) ( M {\hat{I}}_{sd , n}^{i} + {\sum }_{k = 0}^{M - 1} ( {I}_{bal}^{i} ( {t}_{n} + k Δ t ) + {I}_{bal} ( {t}_{n} + k Δ t ) ) )$$

The third parameter

$${α}_{n}^{i}$$

thereby introduces a so-called dead zone mechanism in the estimation method. In other words, for there to be an update, the estimation

$${e}_{n}^{i}$$

must be sufficiently large relative to the measurement uncertainties η₁+η₂.

According to a second example, the estimation function is an observer based on a coulometry model and the reference value is the self-discharge value of a reference electrochemical element 12.

According to a particular example, the reference electrochemical element 12 is the electrochemical element 12 for which the self-discharge value at the previous second instant is the highest.

Such an estimation function thereby allows the estimation to be made of the difference of self-discharge between the considered electrochemical element 12 and that of the reference electrochemical element 12.

In addition to the previous first and second contributions, the estimation function according to the second example also takes into account two additional contributions.

The third contribution corresponds to the variation of the state of charge of the reference electrochemical element between the second estimation instant and the previous second instant.

The fourth contribution corresponds, for its part, to the accumulation of charge in the reference electrochemical element related to the first measurement values in the time interval between the previous second instant and the second estimation instant.

Moreover, as with the previous embodiment, the estimation function is a weighted sum of the contributions and the self-discharge value relative to the reference value at the previous second instant.

The contributions are here weighted by the same gain coefficient.

The estimation function is written mathematically:

$$\text{?} - \text{?} = {K}_{n}^{i} ( Δ {SOC}_{n + 1}^{i} - Δ {SOC}_{n}^{i} - Δ t ( {\sum }_{k = 0}^{M - 1} ( {θ}^{i} {I}_{bal}^{i} ( {t}_{n} + k Δ t ) - {θ}^{{J}_{n}} {I}_{bal}^{{J}_{n}} ( {t}_{n} + k Δ t ) ) + {θ}^{i} M \text{?} + ( {θ}^{i} - {θ}^{{J}_{n}} ) {\sum }_{k = 0}^{M - 1} {I}_{bal} ( {t}_{n} + k Δ t ) ) + ( {SOC}_{n + 1}^{{J}_{n + 1}} - {SOC}_{n + 1}^{{J}_{n}} ) ) .$$

Where:
[symbol] represents the estimation of the self-discharge difference of the i-th electrochemical element 12 relative to the self-discharge of the reference electrochemical element 12,
Jₙ designates the index of the reference electrochemical element, in the described example, due to the choice of the reference electrochemical element, the index Jₙ verifies the following relation:

$${J}_{n} = arg {min}_{i} {SOC}_{n}^{i}$$

$$Δ {SOC}_{n}^{i}$$

is the difference in the state of charge between the i-th electrochemical element and the reference electrochemical element, this value

$$Δ {SOC}_{n}^{i}$$

thereby verifying the following mathematical relation:

$$Δ {SOC}_{n}^{i} = {SOC}_{n}^{i} - {SOC}_{n}^{{J}_{n}}$$

As with the previous case, two examples can be considered in particular for the gain coefficient

$${K}_{n}^{i} .$$

According to the first example, the gain coefficient

$${K}_{n}^{i}$$

is always expressed as follows:

$${K}_{n}^{i} = \frac{{θ}^{i} Δ t M}{{γ}^{2} + {( {θ}^{i} Δ t M )}^{2}}$$

In the case of the second example, the gain coefficient

$${K}_{n}^{i}$$

can be written:

$${K}_{n}^{i} = \frac{{α}_{n}^{i} {θ}^{i} Δ t M}{{γ}^{2} + {( {θ}^{i} Δ t M )}^{2}} ,$$

$$where {α}_{n}^{i} = {p}_{n}^{i} max ( 1 - \frac{{η}_{1} + {η}_{2}}{\vert {e}_{n}^{i} \vert + δ} , 0 )$$

like hereinabove (the quantity still serving to avoid division by 0) but with a new formulation for the estimation

$${e}_{n}^{i}$$

that becomes:

$${e}_{n}^{i} = Δ {SOC}_{n + 1}^{i} - Δ {SOC}_{n}^{i} - Δ t ( {\sum }_{k = 0}^{M - 1} ( \text{?} ( {t}_{n} + k Δ t ) - \text{?} ( {t}_{n} + k Δ t ) ) + \text{?} M Δ \text{?} + \text{?} {\sum }_{k = 0}^{M - 1} \text{?} ( {t}_{n} + k Δ t ) ) + ( SOC \text{?} - SO \text{?} )$$

$$\text{?} \text{indicates text missing or illegible when filed}$$

In each of the cases described hereinabove, a value for the self-discharge of an electrochemical element 12 is obtained at the end of the method. This is schematically represented in FIG. 3 by the circle 38.

Such a method thereby allows a more reliable estimation of the self-discharge to be obtained.

The estimation of the self-discharge may be used for many applications.

According to a first application, the estimation of the self-discharge is used to obtain the dispersion of the state of charge of the electrochemical elements.

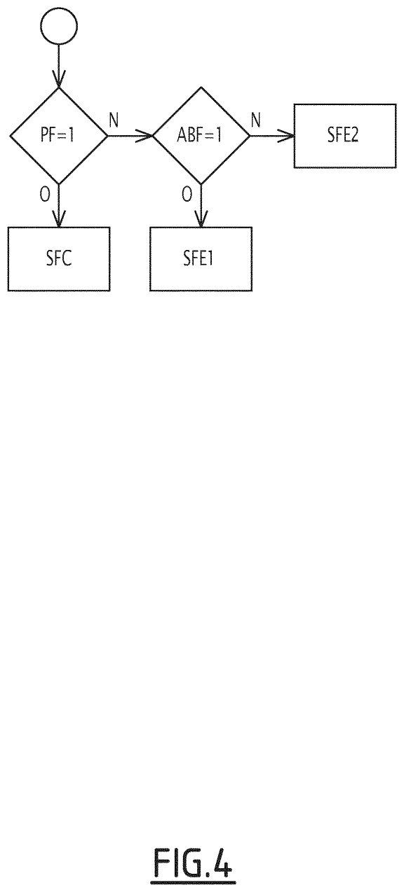

Thereby, as an example, the calculator 22 can also implement a method for evaluating the dispersion of the state of charge of the electrochemical elements according to the flowchart illustrated in FIG. 4.

The method of evaluation includes an implementation step and a determination step.

During the implementation step, the calculator 22 implements the self-discharge estimation method for a plurality of electrochemical elements 12 of the battery 10.

The plurality of electrochemical elements 12 preferably includes all the electrochemical elements 12 of the battery 10.

The calculator 22 thereby allows a self-discharge value relative to the reference value for each electrochemical element 12 of the plurality of electrochemical elements to be obtained.

During the determination step, the calculator 22 determines the dispersion of the state of charge within the plurality of electrochemical elements at an evaluation instant as the difference between the state of charge of the electrochemical element 12 of the plurality of electrochemical elements that is the highest and the state of charge of the electrochemical element 12 of the plurality of electrochemical elements that is the lowest.

Alternatively, it would be possible to consider a determination step during which the estimation of the self-discharge difference relative to the electrochemical element 12 having the highest self-discharge value is used.

According to the example of FIG. 4, the determination step comprises a test operation and an application operation.

During the test operation, one or more predefined criteria are used.

In the described case, two criteria are used.

A first criterion consists of determining whether the evaluation instant corresponds to a second estimation instant.

This test is represented in FIG. 4 by a diamond schematically representing a test of the value of the snapshot variable PF.

If the snapshot variable PF is a first value, this indicates that the snapshot has been taken, whereas if the snapshot variable PF is a second value, this indicates that the snapshot has not been taken.

The snapshot variable PF is thereby, e.g. a Boolean function whose first value is TRUE (noted O in FIG. 4) and the second value is FALSE (noted N in FIG. 4).

A second criterion used during the test operation is to test the state of the balancing circuit at the instant of evaluation.

This test is represented in FIG. 4 by a diamond schematically representing a test of the value of the activation variable ABF.

The activation variable ABF is a Boolean function taking the value TRUE when the balancing circuit 15 is in the active state and FALSE otherwise.

During the application operation, the calculator 22 applies an evaluating function to values used or obtained during the implementation step.

The evaluation calculating function applied is selected according to the result of the test operation.

More precisely, the evaluation calculating function will be selected from several sub-functions based on the predefined criterion or criteria used during the test operation.

In the case illustrated, the calculator 22 has three different sub-functions denoted SFC, SFE1, and SFE2 respectively.

When the first criterion is verified, the calculator 22 applies as a calculating function, a calculating sub-function SFC.

The calculating sub-function SFC calculates the maximum of the difference in states of charge of the electrochemical elements 12 of the plurality of electrochemical elements at the evaluation instant.

Such a calculating sub-function SFC is written:

$$SFC = {min}_{MOWS} ( S {S}_{m e s u r e d} ( {t}_{n + 1} ) )$$

Where:
SS designates the state of charge deviation SS, that is to say, the percentage difference between the most charged electrochemical element 12 and the least charged electrochemical element 12 within the plurality of electrochemical elements, and
MOWS corresponds to the maximum window for observing difference in the state of charges in the measurement zone. Such a window can, e.g. be set as the maximum state of charge level of zone Z1 in FIG. 2,
When the second criterion is verified but not the first criterion, the calculator 22 applies as a calculating function, a first estimation sub-function SFE1.

The first estimation sub-function SFE1 is applied to the values obtained at the end of the implementation step.

Unlike the calculating sub-function SFC which uses measurements also used in the implementation step, the first estimation sub-function SFE1 uses the output data of the implementation step.

The first estimation sub-function SFE1 estimates four contributions to the dispersion, namely:
a first contribution related to the state of charge difference within the plurality of electrochemical elements,
a second contribution related to the self-discharge specific to each electrochemical element 12,
a third contribution related to the maximum self-discharge of all the electrochemical elements 12 of the plurality of electrochemical elements, and
a fourth contribution related to the balancing currents applied to the electrochemical elements 12 of the plurality of electrochemical elements 12.

More precisely, in the described example, the first estimation sub-function SFE1 is written:

$$S F E 1 = S S ( k + 1 ) + D T * ( SBWB ( k ) + M S {D}_{\%} - C S {D}_{\% , i} )$$

Where:
DT designates the time interval between two iterations (in seconds),
SBWB designates the amount of charge balanced by the balancing circuit 15 between instants tₙ and tₙ₊₁ as a percentage of the state of charge of the considered electrochemical element 12, this corresponding to the following formula:

$$SBWB = \frac{1 \; 00 \times {I}_{b a l , i}}{3600 \times {Q}_{i}} [ \% . {s}^{- 1} ]$$

Where i is the index of the considered electrochemical element 12 and I_{bal,i} is the balancing current applied to the electrochemical element 12 in amperes,
MSD_{%}: maximum estimated self-discharge over all the electrochemical elements 12 constituting the plurality of electrochemical elements:

$$M S {D}_{\%} = \frac{100}{3600} {max}_{i ∈ N} \frac{C S {D}_{Ah , i}}{{Q}_{i}} [ \% . {s}^{- 1} ]$$

Where Qᵢ designates the capacity of cell i in Ah and CSD_{Ah,i} the self-discharge of the electrochemical element 12 estimated in A, and
CSD_{%,i}: estimated self-discharge of the i-th considered electrochemical element 12:

$$C S {D}_{\% , i} = \frac{100 \times C S {D}_{A h , i}}{3600 \times {Q}_{i}} [ \% . {s}^{- 1} ]$$

When neither of the two criteria is verified, the calculator 22 applies a second estimation sub-function SFE2.

The calculator 22 thereby applies this second estimation sub-function SFE2 when the balancing circuit 15 is in the active state and the evaluation instant does not correspond to the second estimation instant.

As with the case of the first estimation sub-function SFE1, the second estimation sub-function SFE2 is an estimation function applied to the values obtained at the end of the implementation step.

The second estimation sub-function SFE2 estimates three contributions to the dispersion, namely:
a first contribution related to the state of charge dispersion within the plurality of electrochemical elements,
a second contribution related to the self-discharge specific to each electrochemical element 12, and
a third contribution related to the maximum self-discharge of all the electrochemical elements 12 of the plurality of electrochemical elements.

More precisely, in the example described, the second estimation sub-function SFE2 is written:

$$SFE 2 = S S ( k ) + D T * ( MSD - CSD )$$

In each case, a measured or estimated value for the difference in the state of charge SS is thereby obtained at the end by taking into account the best available values.

The method of evaluation allows the most precise value to be obtained of the difference in the state of charge SS within the plurality of electrochemical elements 1.

According to a second application, the estimation of the self-discharge is used to control the current balancing of the electrochemical elements.

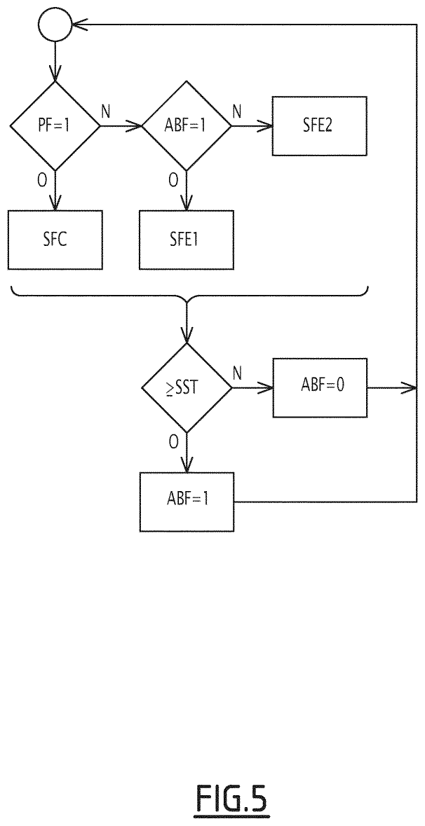

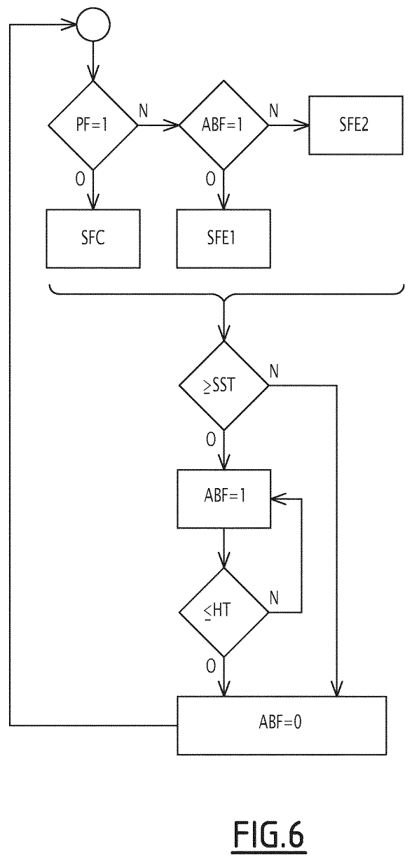

Two specific examples will now be described with reference to the flowcharts of FIGS. 5 and 6.

According to a first example corresponding to FIG. 5, the calculator 22 implements a method for controlling the current balancing of the electrochemical elements.

The method of control includes an implementation step, a comparison step, and a control step.

During the implementation step, the calculator 22 implements the previous method of evaluation to obtain an evaluated dispersion.

The upper part of the figure (before the brace) thereby corresponds to the resumption of the flowchart of FIG. 4.

During the comparison step, the calculator 22 compares the evaluated dispersion with a dispersion threshold SST.

The dispersion threshold SST is a parameter setting the maximum tolerated percentage dispersion in the state of charge in the plurality of electrochemical elements at the time of the snapshots.

The dispersion threshold SST is selected to ensure that the elements are observable at the time of snapshots and prevents the available capacity from being too reduced. A dispersion threshold SST between 1% and 5% usually allows these conditions to be fulfilled. This operation is symbolized in FIG. 5 by a diamond giving the result of the comparison (O for dispersion greater than the dispersion threshold SST and N for a dispersion less than the dispersion threshold SST).

During the control step, the calculator 22 controls the state of the balancing circuit 15 based on the result of the comparison.

According to the described example, the calculator sets the balancing circuit to the active state of the balancing circuit if the evaluated dispersion is greater than or equal to the dispersion threshold.

This is symbolized in FIG. 5 by a rectangle wherein is written ABF=1.

Otherwise, the calculator 22 sets the balancing circuit 15 to the inactive state.

This is schematically illustrated by the rectangle wherein is written ABF=0.

According to a second example corresponding to FIG. 6, an additional test is added.

This test consists of verifying whether the evaluated dispersion is greater than or equal to the dispersion threshold decreased by a hysteresis threshold.

If yes, the calculator 22 keeps the balancing circuit in the active state of the balancing circuit 15.

Otherwise, the calculator 22 sets the balancing circuit to the inactive state, as schematically illustrated by the rectangle wherein is written ABF=0.

Such an additional test prevents the balancing circuit 15 from being locked in active mode.

The previously described balancing method of control allows for the efficient management of the balancing circuit 15 to ensure good balancing of the state of charge of the electrochemical elements 12 within the plurality of electrochemical elements.

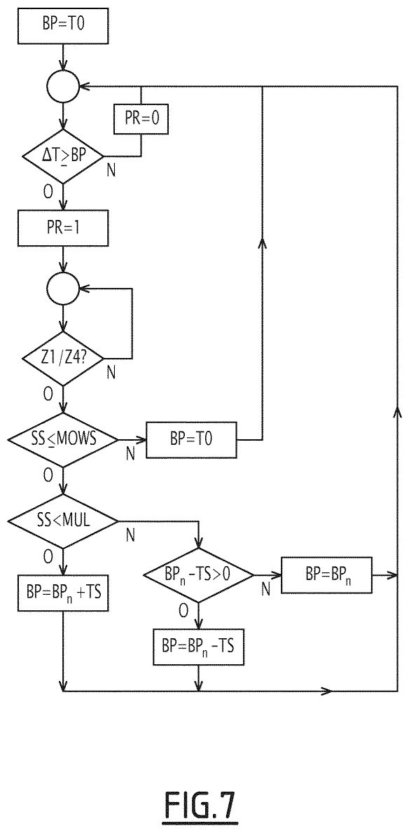

According to a second example corresponding to FIG. 7, the calculator 22 implements a method for controlling the balancing including an implementation step, a comparison step, and a control step.

The implementation and comparison steps are similar to the previous cases. The same remarks thereby apply here and are not repeated.

During the control step, the calculator 22 controls the time interval between two consecutive second instants to be used for subsequent measurements based on the result of the comparison, that is to say, the time interval between two snapshots.

Such a time interval will thereby be called hereinbelow, the measurement interval to clarify the rest of the description.

Ideally, this time interval should be as long as possible to interrupt the use of the battery 10 as little as possible.

The control performed by the calculator 22 can consist of implementing one or more of the operations exposed in what follows.

For example, according to a first operation, the measurement interval is incremented by a first time increment when the evaluated dispersion is less than or equal to a threshold. According to a second operation, the measurement interval is decreased by a second time increment when the evaluated dispersion is less than or equal to the threshold.

According to a third operation, the measurement interval is set to a predefined value if the decrease of the second increment leads to a value lower than the predefined value.

In the three previous operations, the first time increment and the second time increment advantageously may be equal.

According to more complex operations, the first time increment and the second time increment depend on other parameters, e.g. the number of iterations already performed in the implementation of the method or the difference between the evaluated dispersion and the threshold. The lower the dispersion compared to the threshold, the larger the first time increment can be.

For the specific example of FIG. 7, an example of succession of actions is now described.

During an initialization action, the measurement interval BP is initialized to an initial value T0.

This action is represented in FIG. 7 by a rectangle wherein is indicated BP=T0.

As long as the time elapsed since the last snapshot is less than the measurement interval BP, the calculator 22 maintains the variable PR at a first value indicating that a discharge is not necessary.

When the elapsed time becomes greater than or equal, the value of the variable PR is changed to a second value.

This second value corresponds to the fact that a discharge should be performed.

For example, the first value is 0 and the second value is 1, so that the first value corresponds to TRUE while the second value corresponds to FALSE.

This action is schematically represented by a diamond wherein is indicated Δt≥BP and rectangles indicating PR=0 or PR=1 depending on the case.

According to a more elaborate embodiment, this action can include additional criteria, e.g. if the state of charge dispersion exceeds a threshold, switching the variable PR to 1 can also be imposed.

This information on the state of charge dispersion comes here from the method of evaluation described hereinabove.

The calculator 22 then implements a test action to test whether the electrochemical element 12 is in the measurement zone, that is to say, a suitable zone of the SOC/OCV characteristic of FIG. 2.

Such a test action thereby corresponds to a step of testing the validity of the measurement.

This action is schematically represented by a diamond wherein is indicated “Z1/Z4?”.

When the electrochemical element 12 is indeed in the measurement zone, it is then tested whether the difference in the state of charge with balancing is less than or equal to the MOWS value already expressed hereinabove.

In FIG. 7, it is a diamond with the indication SS≤MOWS that corresponds to this action.

If not, the measurement interval BP is reset to the initial value T0 as indicated in the corresponding rectangle of FIG. 7.

Otherwise, the calculator 22 implements a second test.

This test determines whether the difference in the state of charge with balancing is less than or equal to the MUL value.

The MUL value corresponds to the maximum allowed tolerance for the dispersion at the time of measurement.

The MUL value is less than or equal to the MOWS value.

The MUL value in particular can be set to the value of the dispersion threshold SST. As hereinabove, the action corresponding to the second test is represented by a diamond with the indication SS≤MOWS.

If the condition is met, the measurement interval BP is incremented by a predefined time interval TS compared to the current value of the measurement interval noted BPₙ in the corresponding rectangle.

The predefined time TS can be set to the desired value depending on the desired precision when obtaining the measurement interval BP. As a non-limiting example, a value equal to 1 day can be selected.

If not, the current value of the measurement interval BPₙ is compared to the predefined time interval TS.

If the result of the difference is positive (BPₙ>TS), the predefined time interval TS is subtracted [from] the current value of the measurement interval BPₙ to obtain a new value for the measurement interval BP, otherwise, the current value of the measurement interval BPₙ is retained.

Such a method is implemented iteratively until a satisfactory value for the measurement interval BP is obtained.

Such a method of control thereby allows for dynamically adjusting the measurement interval BP. This results in increased availability of the battery 10.

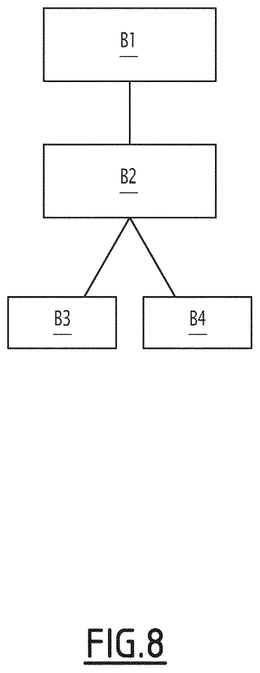

With reference to FIG. 8, which is a block view of the methods that have been described hereinabove, the method includes four blocks: a first block B1 providing a self-discharge value for each electrochemical element 12, a second block B2 giving the dispersion value within the plurality of electrochemical elements 12, a third block B3 controlling the measurement interval, and a fourth block B4 controlling the activation of the balancing circuit 15.

These different blocks are independent in the sense that they only need the output of the previous block to be implemented.

This means that any other way of providing the same value can be considered.

Thereby, as an example, the actions of the third block B3 may be implemented with any method allowing the dispersion value to be obtained within the plurality of electrochemical elements 12, e.g. a combination of blocks B1 and B2 corresponding to the described method, but also a combination of B2 with another block than block B1 or a combination of totally different blocks.

Similar remarks are valid for the second block B2 and the fourth block B4.

In each case, blocks B1 to B4 are advantageously used to ensure better current balancing of the electrochemical elements 12.

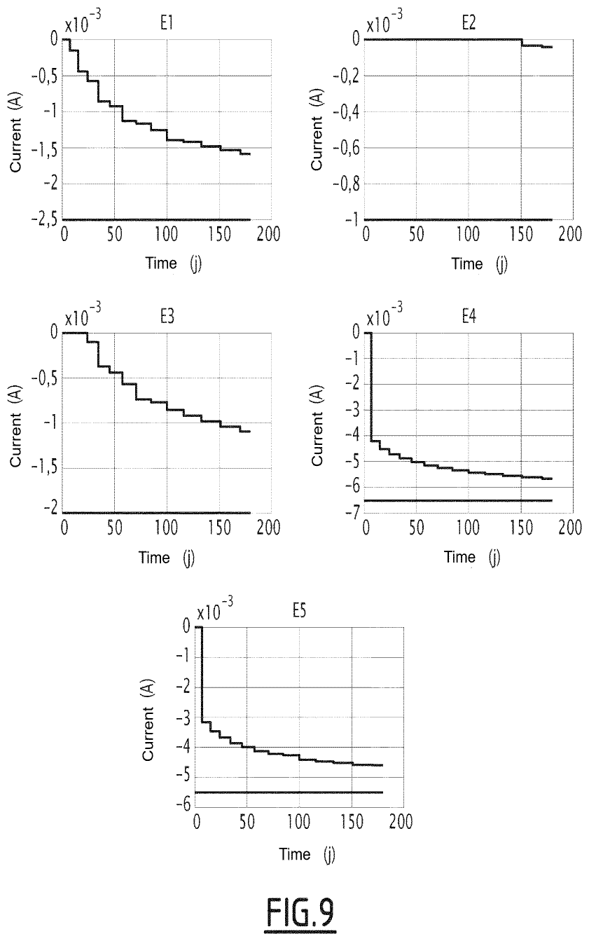

This has been shown in the context of experiments conducted by the Applicant, the results of which are visible in FIGS. 9 to 12.

In these experiments, the battery includes 5 electrochemical elements 12 in series.

The final time considered is 180 days.

The capacities and self-discharge of each electrochemical element 12 are given in the following table:

TABLE 1

| Element | E1 | E2 | E3 | E4 | E5 |
|---|---|---|---|---|---|
| Capacity | 199.64 | 199.5 | 199.09 | 194.95 | 196.33 |
| (A · h) | | | | | |
| Self- | 2.5 | 1 | 2 | 6.5 | 5.5 |
| discharge | | | | | |
| (mA) | | | | | |

The corresponding self-discharge curves for each of the electrochemical elements 12 are given in FIG. 9, which shows the evolution of the current over time.

This information allows the self-discharge dispersion to be obtained by implementing the method of evaluation.

The tolerance for the maximum state of charge dispersion within the battery 10 is set to 1%.

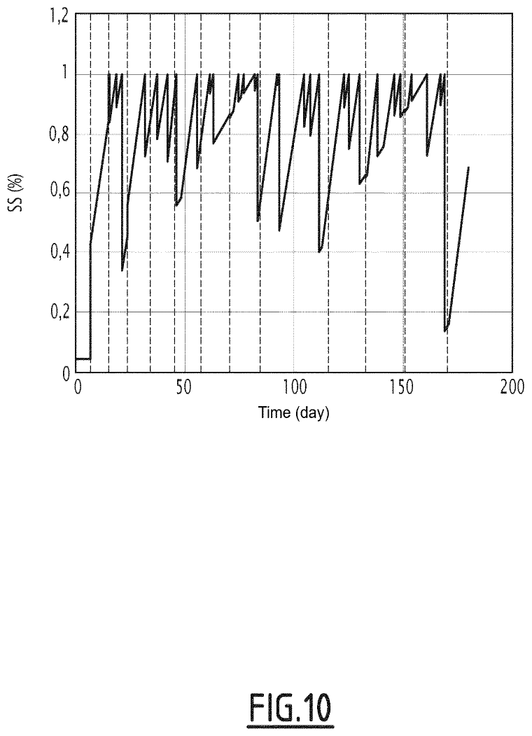

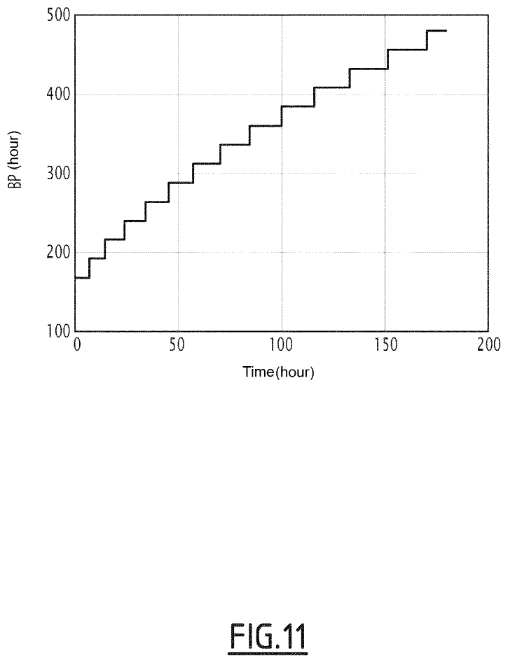

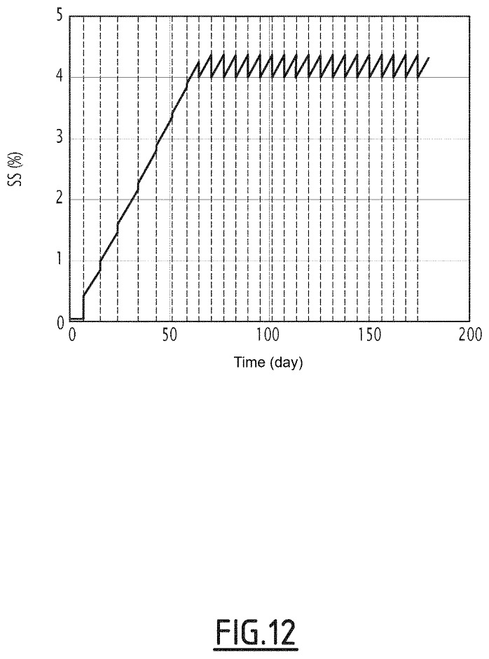

With the implementation of the method, the results of FIGS. 10 and 11 are obtained to be compared to the result of FIG. 12 corresponding to a current balancing without implementation of the method. 5

FIGS. 10 and 12 represent the evolution of the state of charge dispersion over time and with dotted lines, the times at which a snapshot is taken.

FIG. 11 shows how the measurement interval BP increases over time.

It emerges from this comparison that the method allows a reduction to be obtained of a factor of 4 of the state of charge dispersion as well as a gain of a factor of 3 on the measurement interval BP.

The described methods thereby allow better balancing to be obtained with spaced snapshots.

1. A method for estimating the self-discharge of at least one electrochemical element of a battery relative to a reference value, a balancing current specific to the electrochemical element being applied to each electrochemical element, the method being implemented by a calculator, the method comprising, for at least one electrochemical element, the steps of:
obtaining:
the capacity of the electrochemical element,
first measurement values, the first measurement values comprising measurements or estimates of a current of the electrochemical element and the balancing current applied to the electrochemical element at first instants, and
second measurement values, the second measurement values comprising measurements or estimates of the state of charge of the electrochemical element at second instants,
estimating the value of the self-discharge of the electrochemical element at a second instant, denoted second estimation instant, by applying an estimation function to the capacity, the first measurement values, and the second measurement values,
the estimation function calculating two contributions to the self-discharge, a first contribution corresponding to a variation of the state of charge of the electrochemical element between the second estimation instant and a previous second instant and a second contribution corresponding to an accumulation of charge in the electrochemical element related to the first measurement values in a time interval between the previous second instant and the second estimation instant.

2. The method for estimating the self-discharge according to claim 1, wherein the reference value is the self-discharge value of another electrochemical element, and the estimation function also taking into account a third contribution corresponding to the variation of the state of charge of the other electrochemical element between the second estimation instant and the previous second instant and a fourth contribution corresponding to the accumulation of charge in the other electrochemical element related to the first measurement values in the time interval between the previous second instant and the second estimation instant.

3. The method for estimating the self-discharge according to claim 1, wherein the estimation function is a weighted sum of the contributions and the self-discharge value relative to the reference value at the previous second instant.

4. The method for estimating the self-discharge according to claim 3, wherein the contributions are weighted by the same gain coefficient, the gain coefficient depending:
on a first parameter, the first parameter being the product of the capacity of the electrochemical element with the time interval between the previous second instant and the second estimation instant, and
on a second parameter, the second parameter being an adjustable value.

5. The method according to claim 1, further comprising evaluating the dispersion of the state of charge of a plurality of electrochemical elements of the battery, the evaluating the dispersion of the state of charge being implemented by a calculator and comprising:
implementing, for the plurality of electrochemical elements of the battery, the method for estimating the self-discharge of the electrochemical element of the battery relative to a reference value according to claim 1, to obtain a self-discharge value relative to the reference value for each electrochemical element of the plurality of electrochemical elements, and
determining the dispersion of the state of charge within the plurality of electrochemical elements at an evaluation instant as a difference between the state of charge of the electrochemical element of the plurality of electrochemical elements that is the highest and the state of charge of the electrochemical element of the plurality of electrochemical elements that is the lowest, and applying the evaluating function to values used or obtained during the implementing of the method for estimating the self-discharge of the electrochemical element of the battery.

6. The method for according to claim 5, wherein:
the battery is provided with a balancing circuit allowing a respective balancing current to be applied in each electrochemical element of the plurality of electrochemical elements, the balancing circuit presenting two states, an active state and an inactive state, the evaluating function applied being selected between several sub-functions according to at least one predefined criterion.

7. The method according to claim 6, wherein the sub-functions are selected from:
a calculating sub-function calculating the maximum of the difference in states of charge at the evaluation instant.
an estimation function applied to the values obtained at the end of the step of implementing, the estimation function calculating two contributions to the dispersion, a first contribution related to the self-discharge specific to each electrochemical element and a second contribution related to the maximum self-discharge of all the electrochemical elements of the plurality of electrochemical elements, and
a sub-function being an estimation function applied to the values obtained at the end of the step of implementing, the estimation function calculating three contributions to the dispersion, a first contribution related to the self-discharge specific to each electrochemical element, a second contribution related to the maximum self-discharge of all the electrochemical elements of the plurality of electrochemical elements, and a third contribution related to the balancing currents applied to the electrochemical elements of the plurality of electrochemical elements.

8. The method according to claim 6, wherein:
when a criterion according to which the evaluation instant corresponds to the second estimation instant is verified, the evaluating function selected is the calculating sub-function, and
when the balancing circuit is in the active state, the evaluating function selected being the estimation sub-function calculating three contributions, the evaluating function selected is otherwise the estimation sub-function calculating two contributions.

9. The method according to claim 5, further comprising controlling a current balancing of the electrochemical elements of the battery, the battery being provided with a balancing circuit allowing a respective balancing current to be applied in each electrochemical element of the plurality of electrochemical elements, the balancing circuit presenting two states, an active state and an inactive state, the controlling the current balancing comprising:
implementing the method for evaluating the dispersion of the state of charge of the plurality of electrochemical elements of the battery according to claim 5, to obtain an evaluated dispersion,
comparing the evaluated dispersion with a dispersion threshold, and
controlling the state of the balancing circuit based on the result of the comparison by setting the balancing circuit to the active state if the evaluated dispersion is greater than or equal to the dispersion threshold possibly decreased by a hysteresis threshold and setting the balancing circuit to the inactive state otherwise.

10. The method of claim 5, further comprising controlling a current balancing of the electrochemical elements of the battery, the controlling of the current balancing being implemented by a calculator and comprising:
implementing the steps of the method for evaluating the dispersion of the state of charge of the plurality of electrochemical elements of the battery according to claim 5, to obtain an evaluated dispersion,
comparing the evaluated dispersion with a dispersion threshold, and
controlling the time interval between two consecutive second instants to be used for subsequent measurements based on the result of the comparison.

11. The method according to claim 10, wherein the step of controlling includes an increment of the time interval by a first time increment when the evaluated dispersion is less than or equal to the threshold and a decrease of the time interval by a second time increment when the evaluated dispersion is less than or equal to the threshold, the time interval being set to a predefined value if the decrease of the second increment leads to a value lower than the predefined value.

12. The method according to claim 11, wherein the method further includes testing the validity of the measurement, the testing including a test of the amplitude of variation of the dispersion relative to a maximum possible variation value.

13. A calculator adapted to implement the method according to claim 1.

14. A management system for a plurality of electrochemical elements of a battery, the plurality of electrochemical elements having terminals, the management system comprising:
a balancing circuit adapted to apply a respective balancing current to each of the electrochemical elements of the plurality of electrochemical elements,
for each electrochemical element of the plurality of electrochemical elements:
a current sensor delivered by the electrochemical element,
a balancing current sensor applied, and
a voltage sensor adapted to measure the voltage at the terminals of the electrochemical element, and
a calculator according to claim 13.

15. A battery comprising:
electrochemical elements, and
a management system according to claim 14.

16. The method for estimating the self-discharge according to claim 2, wherein the other electrochemical element is the electrochemical element for which the self-discharge value at the previous second instant is the highest.

17. The method for estimating the self-discharge according to claim 4, wherein the gain coefficient further depends from a third parameter taking into account the uncertainty of the second measurements.

18. The method for estimating the self-discharge according to claim 17, wherein the third parameter depends on the ratio between the uncertainty of the second measurements and the value of the contributions.

19. The method for estimating the self-discharge according to claim 17, wherein the gain coefficient is a hyperbolic function that can be written in the form:
$$P 3 \frac{P 1}{P {1}^{2} + P {2}^{2}}$$
with P1 the first parameter, P2 the second parameter, and P3 the third parameter.

20. The method for controlling the balancing according to claim 11 wherein the first time increment and the second time increment are equal.
